(19) United States
(12) Patent Application Publication
(10) Pub. No.: US 2025/0357153 A1
(43) Pub. Date: Nov. 20, 2025

(54) WAFER CLEANING DEVICE

(71) Applicant: SAMSUNG ELECTRONICS CO., LTD., Suwon-si (KR)

(72) Inventors: Imbi Yeo, Suwon-si (KR); Donghoon Kwon, Suwon-si (KR); Youngjin Ye, Suwon-si (KR)

(73) Assignee: SAMSUNG ELECTRONICS CO., LTD., Suwon-si (KR)

(21) Appl. No.: 18/920,068

(22) Filed: Oct. 18, 2024

(30) Foreign Application Priority Data
May 14, 2024 (KR) 10-2024-0063389

(51) Int. Cl. H01L 21/67; A46B 9/00; A46B 9/02; A46B 11/06; A46B 13/00; A46B 13/04; A46B 17/06

(52) U.S. Cl. CPC H01L 21/67046; A46B 9/005; A46B 9/02; A46B 11/063; A46B 13/001; A46B 13/008; A46B 13/04; A46B 17/06; A46B 2200/3073

(57) ABSTRACT

A wafer cleaning device according to an embodiment includes a brush module configured to face one surface of at least one wafer and rotate around a central axis of the brush module; and at least one support that is adjacent to the brush module and configured to support the one surface of the at least one wafer, wherein the brush module includes a plurality of brushes sharing the central axis.

### CROSS-REFERENCE TO RELATED APPLICATION

This application claims priority to and the benefit of Korean Patent Application No. 10-2024-0063389, filed at the Korean Intellectual Property Office on May 14, 2024, the entire contents of which are incorporated herein by reference.

### BACKGROUND

### 1. Field

Embodiments of the present disclosure relate to a wafer cleaning device.

### 2. Description of Related Art

A chemical mechanical polishing (CMP) process (or a chemical mechanical planarization (CMP) process) of a semiconductor is a process of planarizing a wafer surface using a chemical reaction and a mechanical force. The CMP process is a highly precise process in which not only a mechanical factor such as rotation speeds of a polishing pad and a wafer, a pressure applied to the wafer, pattern directionality of the pad, or the like act as important variables, but also a chemical influence such as an interaction between a slurry polishing particle and the wafer surface, a role of a slurry organic additive, or the like act as important variables.

After a polishing process within a CMP facility is completed, a cleaning process for removing a particle is performed, and the cleaning process is a process of removing various particles such as a foreign substance on the wafer surface, a metal particle, an organic pollutant, and an unnecessary thin film, and the like using physical and chemical methods.

In a case of CMP in-situ cleaning in which processes such as polishing, cleaning, and the like are carried out in-situ within the same system, a method of cleaning both surfaces of the wafer using a roll brush disposed above both surfaces of the wafer is generally used.

However, if the wafer is cleaned using the above method, there is a problem in which the roll brush is in excessive contact with a center region of the wafer, and the roll brush is reversely contaminated or worn so that there is an inconvenience of having to replace the roll brush regularly.

### SUMMARY

Embodiments of the present disclosure may solve the above problems, and may include a wafer cleaning device that increases wafer cleaning power by cleaning a wafer using a brush module including a plurality of brushes capable of being independently rotated based on a central axis.

In addition, embodiments of the present disclosure may include a wafer cleaning device in which the brush module evenly contacts an entire region of the wafer because the brush module may move in a horizontal direction, so that a problem according to a comparative embodiment in which a roll brush is in excessive contact with a center region of the wafer is solved.

In addition, embodiments of the present disclosure may include a wafer cleaning device with a structure in which at least one wafer may be disposed above an upper surface of the brush module and may be cleaned at the same time and that minimizes an area of a wafer cleaning facility and improves productivity because cleaning of multiple wafers is possible.

In addition, embodiments of the present disclosure may include a wafer cleaning device that enables self-cleaning of the brush module to prevent reverse contamination of the brush module and to lengthen a replacement cycle of the brush module.

According to embodiments of the present disclosure, a wafer cleaning device may be provided and include: a brush module configured to face one surface of at least one wafer and rotate around a central axis of the brush module; and at least one support that is adjacent to the brush module and configured to support the one surface of the at least one wafer, wherein the brush module includes a plurality of brushes sharing the central axis.

According to embodiments of the present disclosure, a wafer cleaning device may be provided and include: a brush module including an upper surface that is configured to face a first surface of a wafer, the brush module configured to rotate around a central axis of the brush module; a head portion including at least one body that is above the brush module, the at least one body configured to rotate around an axis of the head portion in a state in which the at least one body supports a second surface of the wafer, opposite of the first surface; and a cleaner that is configured to supply a cleaning solution to the upper surface of the brush module, wherein the brush module includes a plurality of brushes that are configured to rotate around the central axis.

According to embodiments of the present disclosure, a wafer cleaning device may be provided and include: a brush module including a plurality of brushes sharing a central axis, the plurality of brushes configured to independently rotate around the central axis, and an upper surface of the brush module is configured to face a first surface of a wafer; and a brush cleaner above the brush module and configured to clean the upper surface of the brush module, wherein the brush cleaner includes: an arm; and a cleaning solution outlet that is on the arm and configured to supply a cleaning solution toward the upper surface of the brush module.

Embodiments of the present disclosure may solve a problem of over-contact between a wafer and a brush module because the brush module is in uniform contact with a surface of the wafer, and may improve productivity because a plurality of wafer cleaning operations may be simultaneously performed in one brush module.

### BRIEF DESCRIPTION OF DRAWINGS

FIG. 1 is a view shown to describe a process according to a comparative embodiment in which a roll brush cleans a wafer.

FIG. 2 is a view shown to describe a wafer cleaning device according to an embodiment of the present disclosure.

FIG. 3 is a view shown to describe another embodiment of the wafer cleaning device of FIG. 2.

FIG. 4 is a view shown to describe another embodiment of the wafer cleaning device of FIG. 2.

FIG. 5 is a view shown to describe a brush module of the wafer cleaning device according to an embodiment of the present disclosure.

FIGS. 6A to 8 are views for describing the brush module according to various embodiments.

FIG. 9A is a view shown to describe a nodule disposed on the brush module, according to embodiments of the present disclosure.

FIG. 9B is a magnified view of a region A of FIG. 9A, according to embodiments of the present disclosure.

FIG. 10A is a view shown to describe a nodule disposed on the brush module, according to embodiments of the present disclosure.

FIG. 10B is a magnified view of a region B of FIG. 10A, according to embodiments of the present disclosure.

FIG. 10C is a magnified view of the region B of FIG. 10A, according to embodiments of the present disclosure.

FIG. 10D is a magnified view of the region B of FIG. 10A, according to embodiments of the present disclosure.

FIG. 11A is a view shown to describe a nodule disposed on the brush module, according to embodiments of the present disclosure.

FIG. 11B is a magnified view of a region C of FIG. 11A, according to embodiments of the present disclosure.

FIG. 11C is a magnified view of the region C of FIG. 11A, according to embodiments of the present disclosure.

FIG. 11D is a magnified view of the region C of FIG. 11A, according to embodiments of the present disclosure.

FIG. 12A is a view shown to describe a nodule disposed on the brush module, according to embodiments of the present disclosure.

FIG. 12B is a magnified view of a region D of FIG. 12A, according to embodiments of the present disclosure.

FIG. 12C is a magnified view of the region D of FIG. 12A, according to embodiments of the present disclosure.

FIG. 12D is a magnified view of the region D of FIG. 12A, according to embodiments of the present disclosure.

FIG. 12E is a magnified view of the region D of FIG. 12A, according to embodiments of the present disclosure.

FIG. 13 is a view shown to describe a wafer cleaning device according to another embodiment of the present disclosure.

FIGS. 14A to 17B are views for describing a wafer cleaning device according to another embodiment of the present disclosure.

### DETAILED DESCRIPTION

Non-limiting example embodiment of the present disclosure will be described more fully hereinafter with reference to the accompanying drawings so that those skilled in the art easily implement embodiments of the present disclosure. Embodiments of the present disclosure may be modified in various different ways, all without departing from the spirit and scope of the present disclosure.

In order to clearly describe embodiments of the present disclosure, parts or portions that are irrelevant to the description may be omitted, and identical or similar constituent elements throughout the specification may be denoted by the same reference numerals.

Further, in the drawings, the size and thickness of each element may be arbitrarily illustrated for ease of description, and embodiments of the present disclosure are not necessarily limited to the example embodiments illustrated in the drawings. In the drawings, the thicknesses of layers, films, panels, regions, areas, etc., may be exaggerated for clarity. In the drawings, for ease of description, the thicknesses of some layers and areas may be exaggerated.

Throughout the specification, when a part is “connected” to another part, it includes not only a case where the part is “directly connected” but also a case where the part is “indirectly connected” with another part in between. In addition, unless explicitly described to the contrary, the word “comprise” (or “include”) and variations such as “comprises” (or “includes”) or “comprising” (or “including”) will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

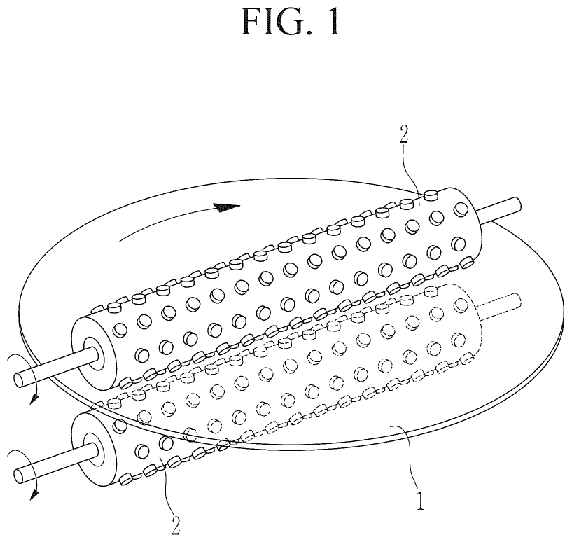

FIG. 1 is a view shown to describe a process according to a comparative embodiment in which a roll brush cleans a wafer.

FIG. 1 is a view shown to describe a general method of cleaning a wafer 1 used in CMP in-situ cleaning. As shown in FIG. 1, roll brushes 2 are disposed above both surfaces of the wafer 1, and the roll brushes 2 rotated based on respective axes. The roll brushes 2 rotate in contact with the wafer 1 disposed between the roll brushes 2, and surfaces of the wafer 1 are cleaned while the roll brushes 2 rotate.

In a case of the above method, there is a problem in which the roll brushes 2 are in excessive contact with a center region of the wafer 1. In addition, because the roll brushes 2 are reversely contaminated or worn due to a contact between the roll brushes 2 and the wafer 1, there is an inconvenience in which a process of regularly replacing the roll brushes 2 is required.

Accordingly, there is a need in which the problem in which the roll brushes 2 are in excessive contact with the center region of the wafer 1 is reduced and a replacement cycle of the brush module is lengthened to increase efficiency by enabling self-cleaning of the brushes themselves.

Hereinafter, a wafer cleaning device 10 according to embodiments of the present disclosure will be described in more detail with reference to the drawings.

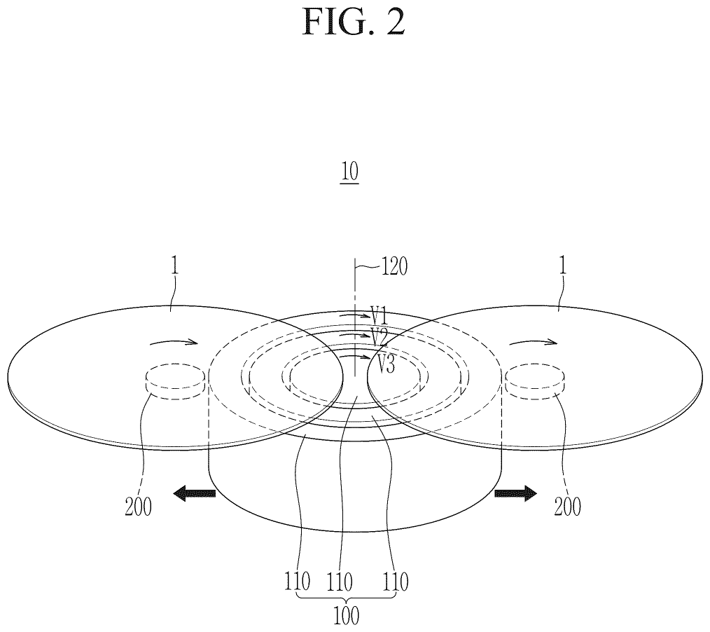

FIG. 2 is a view shown to describe the wafer cleaning device according to an embodiment of the present disclosure.

As shown in FIG. 2, the wafer cleaning device 10 according to an embodiment of the present disclosure may remove a slurry residue and a contaminant remaining on a wafer 1 after polishing in a CMP process, and may clean the wafer 1.

The wafer cleaning device 10 according to an embodiment of the present disclosure may include a brush module 100 that is disposed so that an upper surface thereof faces one surface of the wafer 1 and is rotatable with respect to a central axis 120 and a support portion 200 (e.g., a support) that is disposed close (e.g., adjacent) to a side surface of the brush module 100 to support one surface of the wafer 1.

As shown in FIG. 2, the brush module 100 may include a plurality of brushes 110 that share a central axis 120.

FIG. 2 shows three brushes 110, but the brush module 100 may include up to five brushes 110 sharing the central axis 120.

The plurality of brushes 110 may be made of a poly vinyl acetate (PVA) material. The PVA has an advantage of being a material with a high moisture content and strong durability and elasticity.

However, a material of the brush 110 is not limited to the PVA. Because required conditions vary depending on a type of a pollutant generated in the CMP process, a type of film quality generated in the CMP process, and a slurry used in the CMP process, the material of the brush 110 may further include a different material suitable for each condition. For example, the material of the brush 110 may include various polymer materials such as Polyurethane (PU), Nylon Polypropylene (PP), and diamond.

All of the plurality of brushes 110 may be made of the same material as each other, or the plurality of brushes 110 may be made of different materials from each other.

At least one wafer 1 may be disposed above an upper surface of the brush module 100 and may rotate. Each brush 110 of the brush module 100 may rotate in the same direction as a rotation direction of the at least one wafer 1.

Here, a rotation of the wafer 1 may be rotated by a rotational force transferred from a support portion 200 supporting the wafer 1. However, embodiments of the present disclosure are not limited thereto. According to some embodiments of the present disclosure, a separate configuration for rotating the wafer 1 may be further included.

The plurality of brushes 110 may be independently rotated with respect to the central axis 120.

To describe an independent rotation of the plurality of brushes 110, the a brush 110 disposed at a center region of the wafer 1 shown in FIG. 2 may be referred to as a first brush, the brush 110 disposed outside the first brush may be referred to as a second brush, and the brush 110 disposed outside the second brush may be referred to as a third brush.

Each of the first brush, the second brush, and the third brush may have the same rotation direction. If the rotation directions are different, a scratch or the like may occur at the wafer 1 in contact with the brush 110, and there is a possibility that the cleaning power may be lowered.

If a rotation speed of the first brush is v3, a rotation speed of the second brush is v2, and a rotation speed of the third brush is v1, v1, v2, and v3 may all have the same value, but at least one value among v1, v2, and v3 may be different.

The brush module 100 of the wafer cleaning device 10 according to embodiments of the present disclosure may include a plurality of brushes 110 that are disc-shaped and may be independently rotated based on the central axis 120, and cleaning power for the wafer 1 may be increased using the plurality of brushes 110 that are disc-shaped.

The support portion 200 may be disposed so that an upper surface of the support portion 200 faces one surface of the wafer 1, and may be disposed close (e.g., adjacent) to a side surface of the brush module 100.

As shown in FIG. 2, the support portion 200 may be spaced apart from the side surface of the brush module 100 at a predetermined interval so that the support portion 200 may be disposed close (e.g., adjacent) to the brush module 100 without the support portion 200 and the brush module 100 contacting each other.

In other words, the support portion 200 and the brush module 100 may be disposed to be spaced apart by the predetermined interval. This is to provide a distance so that the brush module 100 may move in a direction (e.g., a horizontal direction) in which each support portion 200 is disposed.

In the wafer cleaning device 10 according to embodiments of the present disclosure, the wafer 1 may evenly contact an entire region of the brush module 100 because the brush module 100 may move in the horizontal direction by a distance that does not cause the brush module 100 to collide with the support portion 200. Particularly, it is possible to prevent the brush module 100 from being in excessive contact with the center region of the wafer 1.

The support portion 200 of embodiments of the present disclosure may have a structure in direct contact with one surface of the wafer 1. In this case, as described above, the wafer 1 also rotates according to a rotation of the support portion 200.

According to another embodiment, the support portion 200 may support the one surface of the wafer 1, but may maintain a non-contact state with the one surface of the wafer 1. Specifically, the support portion 200 may supply a fluid toward the one surface of the wafer 1 to support the wafer 1 in the non-contact state with the one surface of the wafer 1.

For example, the support portion 200 may spray a liquid or a gas from an upper surface of the support portion 200 toward the one surface of the wafer 1, such that a pressure is applied toward the one surface of the wafer 1. Due to the pressure, the support portion 200 may maintain the non-contact state with the one surface of the wafer 1, and may simultaneously support the wafer 1.

There may be a plurality of wafers 1 disposed at an upper portion of the brush module 100. However, the plurality of wafers 1 do not necessarily have to be disposed at the upper portion of the brush module 100, and only one wafer 1 may be disposed at the upper portion of the brush module 100.

FIG. 2 shows an embodiment in which two wafers 1 are disposed at the upper portion of the brush module 100. If the plurality of wafers 1 are disposed at the upper portion of the brush module 100 as shown in FIG. 2, the plurality of wafers 1 may be disposed so that at least a portion of the plurality of wafers 1 faces an upper surface of the brush module 100.

According to some example embodiments of the present disclosure, up to three wafers 1 may be disposed at the upper portion of the brush module 100.

The wafer cleaning device 10 according to embodiments of the present disclosure may have a structure in which one or more wafers 1 may be disposed above the upper surface of the brush module 100, so that the one or more wafers 1 may be simultaneously cleaned using one brush module 100. Accordingly, there is an effect in which an area of a facility cleaning the wafer 1 may be minimized and the plurality of wafers 1 may be simultaneously cleaned so that productivity is improved.

As shown in FIG. 2, only a portion of the one surface of the wafer 1 is disposed to face the upper surface of the brush module 100, and there is no problem in which the brush module 100 is in excessive contact with a portion (e.g., a center portion) of the wafer 1.

This is because each of the plurality of brushes 110 may be independently rotated with reference to the central axis 120 and simultaneously the brush module 100 may move in the horizontal direction.

The brush module 100 and the support portion 200 may be disposed to be spaced apart by a predetermined interval, and the brush module 100 may be horizontally moved within the predetermined interval. In other words, the brush module 100 has a structure capable of sweeping in the horizontal direction.

Additionally, the support portion 200 supporting the one surface of the wafer 1 may not be disposed at the center region that is an exact center of the wafer 1. In other words, the support portion 200 may have a structure for supporting the wafer 1 by being disposed at a position slightly off the center of the wafer 1.

If the support portion 200 is disposed at the center of the wafer 1, the center region of the wafer 1 may be covered by the support portion 200 even if both the wafer 1 and the brush module 100 rotate, so that the brush module 100 may not clean the center region of the wafer 1.

In other words, because the support portion 200 is disposed at the position slightly off the center of the wafer 1, an entire region of the wafer 1 may be in contact with the brush module 100 by a rotation of the wafer 1.

At the same time, as described above, the brush module 100 may be swept in the horizontal direction and the plurality of brushes 110 may be independently rotated based on the central axis 120, so that there is no problem in which the brush module 100 is in excessive contact with a portion (e.g., the center portion) of the wafer 1. In conclusion, cleaning power for the entire region of the wafer 1 may be improved.

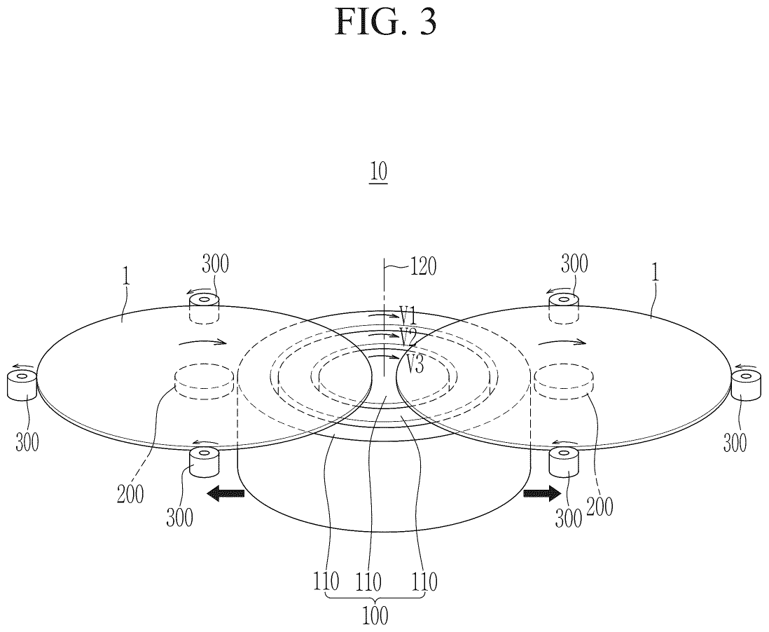

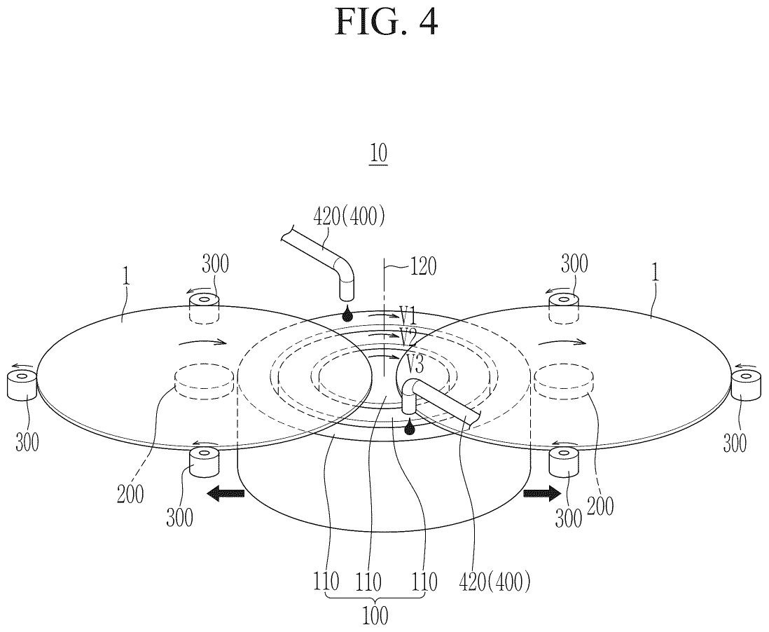

FIG. 3 and FIG. 4 are views shown to describe another embodiment of the wafer cleaning device of FIG. 2.

First, as shown in FIG. 3, the wafer cleaning device 10 may further include a roller 300 disposed in contact with a side surface of a wafer 1. The roller 300 may be disposed to surround an edge of the wafer 1.

The roller 300 may be disposed so that a rotation surface thereof is in contact with the side surface of the wafer 1, and there may be at least one roller 300 disposed in contact with one wafer 1. For example, at least one roller 300 may be provided for each wafer 1.

As the roller 300 rotates, the wafer 1 may rotate together. The roller 300 may rotate the wafer 1, and at the same time, may prevent the wafer 1 supported by the support portion 200 from deviating from a predetermined position.

FIG. 4 shows an embodiment in which a cleaning portion 400 (e.g., a cleaner) for supplying a cleaning solution to an upper surface of a brush module 100 is further included in the wafer cleaning device 10 shown in FIG. 3.

As shown in FIG. 4, the wafer cleaning device 10 may further include a cleaning arm 420 disposed at an upper portion of the brush module 100 to supply a cleaning solution to an upper surface of the brush module 100.

The cleaning arm 420 having an arm shape may further increase cleaning efficiency in a process in which the brush module 100 cleans the wafer 1 by spraying a cleaning solution on an upper surface of a brush 110.

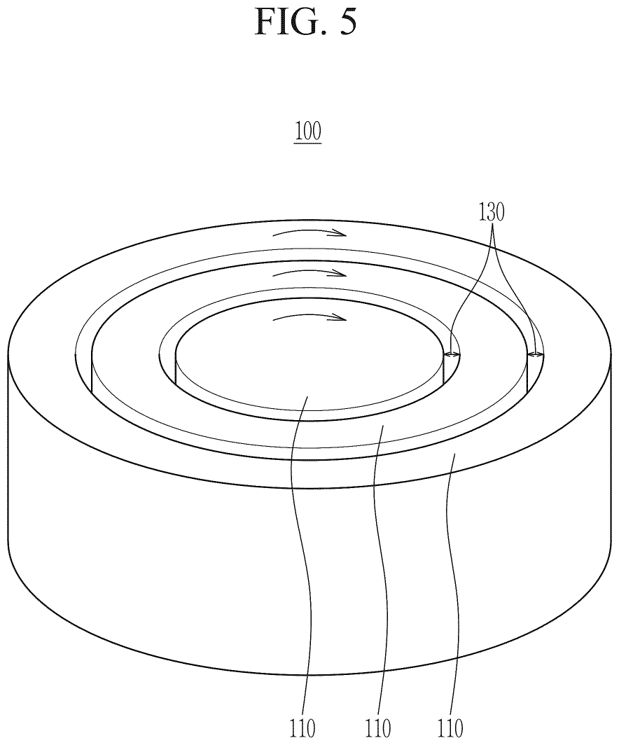

FIG. 5 is a view shown to describe the brush module of the wafer cleaning device according to an embodiment.

FIG. 5 is a view showing only the brush module 100 in order to describe a structure of the brush module 100 in the wafer cleaning device 10 according to an embodiment of the present disclosure.

As shown in FIG. 5, gaps 130 may be disposed between the plurality of brushes 110.

Each of the plurality of brushes 110 may be independently rotated, and the plurality of brushes 110 may not be in an integrated form. For example, the plurality of brushes 110 may have separate structures from each other. For example, according to an embodiment, the gaps 130 may be included between each of the plurality of brushes 110.

The gaps 130 may each have a width that does not interfere with a rotation of each brush 110. For example, the width of each of the gaps 130, which may be a distance between neighboring ones of the plurality of brushes 110, may be 3 mm or more.

The widths of the gaps 130 do not have to be the same. Additionally, one gap 130 having a concentric shape does not have to have a constant width in all sections.

Because each brush 110 may be independently rotated due to presence of the gaps 130, the width of the gaps 130 is not limited to a constant value.

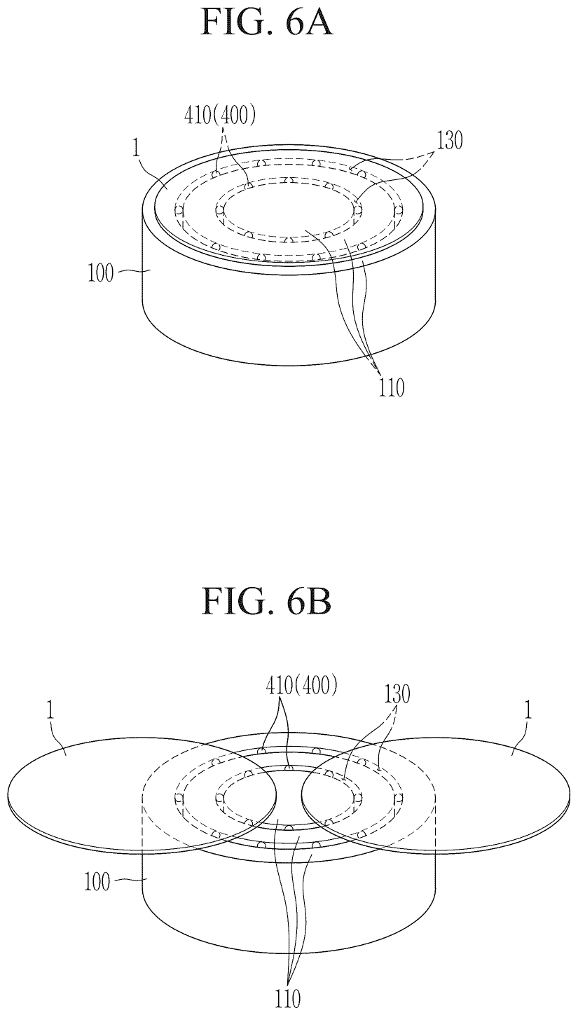

FIGS. 6A to 8 are views for describing the brush module according to various embodiments.

First, in the embodiment shown in FIG. 4, the cleaning portion 400 may include the cleaning arm 420 that is disposed above the brush module 100 and has the arm shape.

As shown in FIG. 6A-B, in the wafer cleaning device 10 according to an embodiment of the present disclosure, the cleaning portion 400 may further include at least one cleaning nozzle 410 to supply the cleaning solution.

As shown in FIGS. 6A to 8, the at least one cleaning nozzle 410 may be disposed in one or more gaps 130 of the brush module 100. The at least one cleaning nozzle 410 disposed in the one or more gaps 130 may supply a cleaning solution to the upper surface of the brush module 100 by spraying the cleaning solution upward.

If the at least one cleaning nozzle 410 is disposed in the one or more gaps 130, the width of the gaps 130 may be 6 mm or more.

A diameter of the cleaning nozzle 410 may be approximately 3 mm, and if a cleaning nozzle 410 is disposed in a gap 130, a margin interval therebetween may be about 3 mm.

As shown in FIG. 6A and FIG. 6B, cleaning nozzles 410 may be evenly disposed in each of the gaps 130.

FIG. 6A shows a case where one wafer 1 is disposed above the upper surface of the brush module 100, and FIG. 6B shows a case where two wafers 1 are disposed above the upper surface of the brush module 100.

Referring to FIG. 6B, the at least one cleaning nozzle 410 may be disposed below the wafer 1 to directly spray the cleaning solution toward the one surface of the wafer 1. In addition, at least one cleaning nozzle 410 may be disposed at an upper surface region of the brush module 100 where the wafer 1 is not disposed to spray the cleaning solution such that the cleaning solution is supplied to an upper surface of the brush 110. Thus, the cleaning nozzle 410 may wet the upper surface of the brush 110 with the cleaning solution.

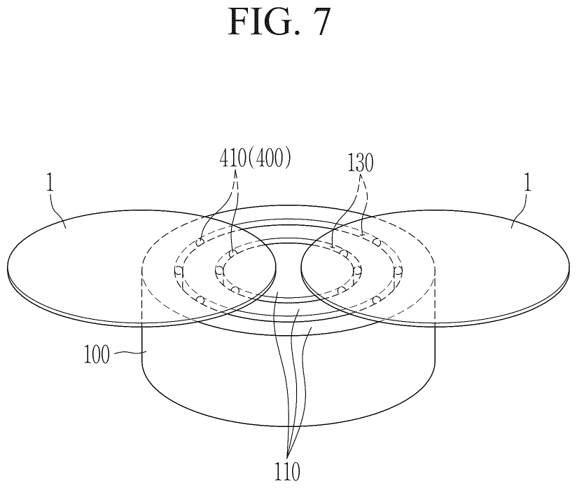

FIG. 7 shows a case where two wafers 1 are disposed above the upper surface of the brush module 100. Unlike FIG. 6B, the at least one cleaning nozzle 410 may be disposed only at an upper surface region of the brush module 100 in contact with the wafer 1.

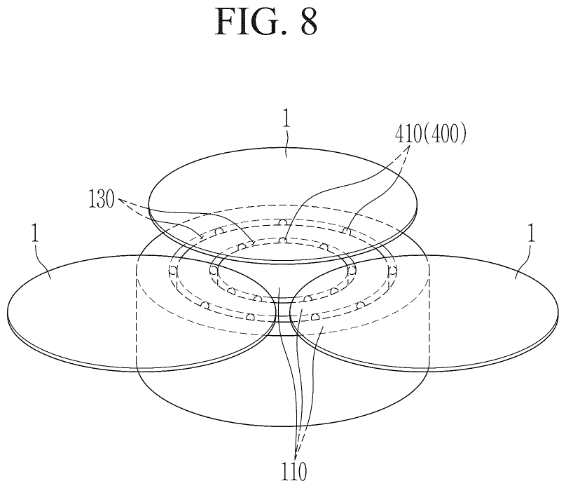

FIG. 8 shows a case in which three wafers 1 are disposed above the upper surface of the brush module 100. Like FIG. 7, FIG. 8 corresponds to a case where the at least one cleaning nozzle 410 is disposed only in partial regions of the gaps 130 that are overlapped by the wafer 1.

In FIGS. 6 to 8, an example in which the at least one cleaning nozzle 410 is disposed is shown, and a position where the at least one cleaning nozzle 410 is disposed is not limited to the positions shown in FIGS. 6 to 8. The at least one cleaning nozzle 410 may be variously disposed depending on the number of wafers 1.

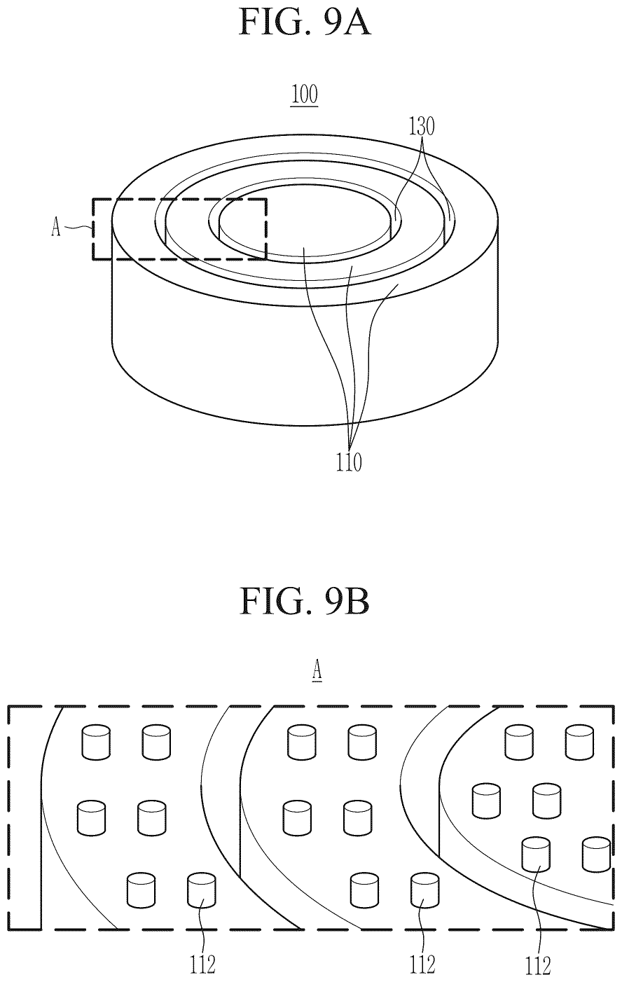

FIGS. 9A to 12E are views shown to describe various embodiments of a nodule disposed on the brush module.

FIG. 9A is a view shown to describe a nodule disposed on the brush module, according to embodiments of the present disclosure. FIG. 9B is a magnified view of a region A of FIG. 9A, according to embodiments of the present disclosure.

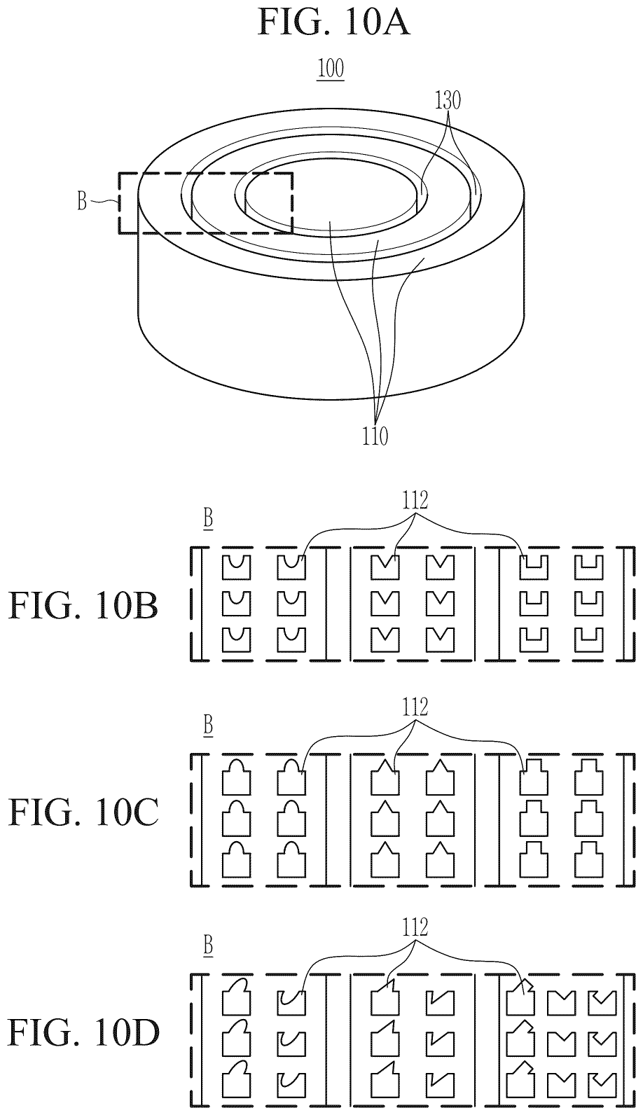

FIG. 10A is a view shown to describe a nodule disposed on the brush module, according to embodiments of the present disclosure. FIGS. 10B to 10D are magnified views of a region B of FIG. 10A, according to embodiments of the present disclosure.

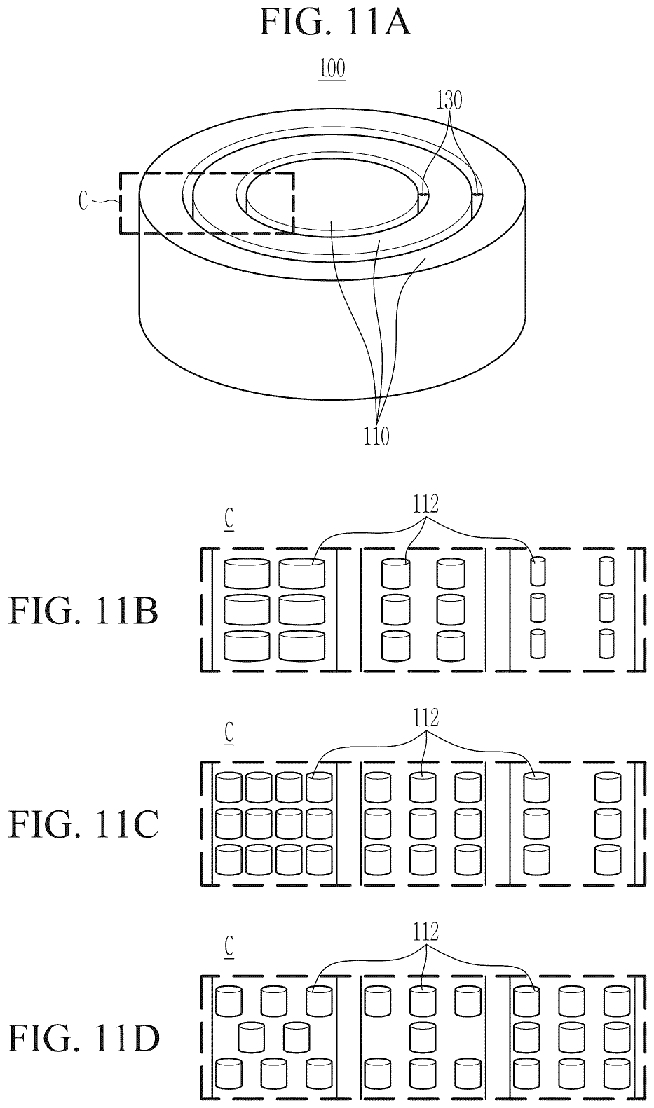

FIG. 11A is a view shown to describe a nodule disposed on the brush module, according to embodiments of the present disclosure. FIGS. 11B to 11D are magnified views of a region C of FIG. 11A, according to embodiments of the present disclosure.

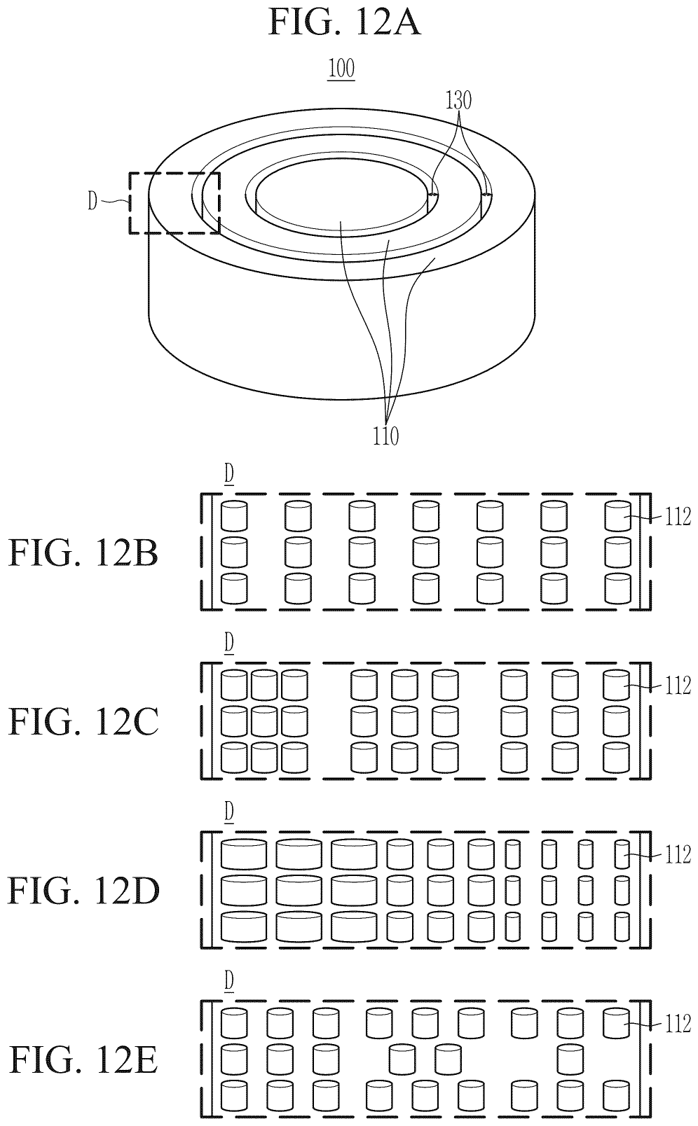

FIG. 12A is a view shown to describe a nodule disposed on the brush module, according to embodiments of the present disclosure. FIGS. 12B to 12E are magnified views of a region D of FIG. 12A, according to embodiments of the present disclosure.

As shown in an enlarged view of a portion of the upper surface of the brush module 100, the nodule 112 may be disposed on the upper surface of the brush module 100. That is, a plurality of nodules 112 may be disposed at each of the plurality of brushes 110.

The nodule 112 may have a shape protruding from a surface of the brush 110. In this case, the protruding portion is in contact with one surface of the wafer 1, and in a process in which the brush 110 and the wafer 1 respectively rotate, the nodule 112 removes a pollutant from a surface of the wafer 1.

In a cleaning process of the wafer 1, a range in which the nodule 112 rubs against the surface of the wafer 1 varies depending on a shape of the nodule 112. Accordingly, a difference occurs in a degree of wear of the nodule 112. This is also related to a lifespan of the brush 110 itself.

The nodule 112 disposed on an upper surface of each brush 110 according to an embodiment of the present disclosure may have various shapes, densities, dispositions, and the like. Additionally, the plurality of nodules 112 disposed on the upper surface of one brush 110 may have various shapes, densities, and dispositions.

FIGS. 9A to 12E are views for describing various embodiments of the nodule 112. For convenience of description, the brush 110 disposed at a center of the brush module 100 is referred to as a first brush, the brush 110 disposed outside the first brush is referred to as a second brush, and the brush 110 disposed outside the second brush is referred to as a third brush.

First, referring to FIGS. 9A to 9B, the plurality of nodules 112 disposed on the upper surface of each brush 110 may be disposed in the same manner for each brush 110.

That is, the nodules 112 on the first brush, the second brush, and the third brush all have the same shape, and are uniformly disposed. The embodiment shown in FIGS. 9A to 9B corresponds to a case in which shapes, sizes, a density, and a disposition interval of the nodules 112 are all constant for all brushes 110.

Referring to FIG. 10B and FIG. 10C, a plurality of nodules 112 disposed on the upper surface of each brush 110 may have different shapes for each brush 110. That is, the nodules 112 disposed on each of the first brush, the second brush, and the third brush may have different shapes.

In FIG. 10B and FIG. 10C, the plurality of nodules 112 disposed on one brush 110 have the same shape, and the number of the nodules 112 disposed on each brush 110 is the same.

In contrast, in the embodiment shown in FIG. 10D, the nodules 112 having two or more shapes are disposed on one brush 110.

Additionally, the number of the nodules 112 is differently disposed in each brush 110. For example, the number of the plurality of nodules 112 disposed on the first brush is greater than the number of the plurality of nodules 112 disposed on each of the second brush and the third brush.

As shown in FIGS. 10B to 10D, the nodule 112 may have various shapes such as a concave shape, a protruding shape, a shape inclined to one side, and the like.

Referring to FIGS. 11A to 11D, the plurality of nodules 112 disposed on the upper surface of each brush 110 may have at least one from among different shapes, densities, and dispositions (e.g., arrangements) for each brush 110.

First, the embodiment shown in FIG. 11B corresponds to a case where a pitch of the nodules 112 disposed on each brush 110 varies. The embodiment shown in FIG. 11C corresponds to a case where the nodules 112 having the same shape are disposed but densities of the nodules 112 are different from each other. The embodiment shown in FIG. 11D corresponds to a case where the nodules 112 with the same shape are disposed but densities and disposition (e.g., arrangement) forms of the nodules 112 are different.

According to an embodiment, pitches, densities, and disposition (e.g., arrangement) forms of the plurality of nodules 112 disposed on each brush 110 may be provided to have a predetermined rule toward the first brush, the second brush, and the third brush as the plurality of nodules 112 move toward the first brush, second brush, and third brush. For example, the density of the plurality of nodules 112 may increase or decrease in one direction.

However, embodiments of the present disclosure are not limited thereto, and a shape and a disposition of the nodules 112 may be irregularly disposed.

FIGS. 12A to 12D are views for describing the nodule 112 disposed on any one brush 110 (e.g., the third brush).

First, referring to FIG. 12B, it may be seen that the nodules 112 having the same shape are uniformly disposed at a predetermined density in one brush 110.

Referring to FIG. 12C, FIG. 12D, and FIG. 12E, it may be seen that shapes, pitches, densities, and disposition forms of the nodules 112 on one brush 110 may be variously provided.

For example, the plurality of nodules 112 having a plurality of shapes may be disposed on an upper surface of any one of the plurality of brushes 110.

Additionally, the plurality of nodules 112 disposed on one brush 110 may have different disposition structures depending on their shapes. The plurality of nodules 112 disposed on the upper surface of each brush 110 may be disposed with a rule as shown in FIG. 12B, FIG. 12C, and FIG. 12D, or may be irregularly provided as shown in FIG. 12E.

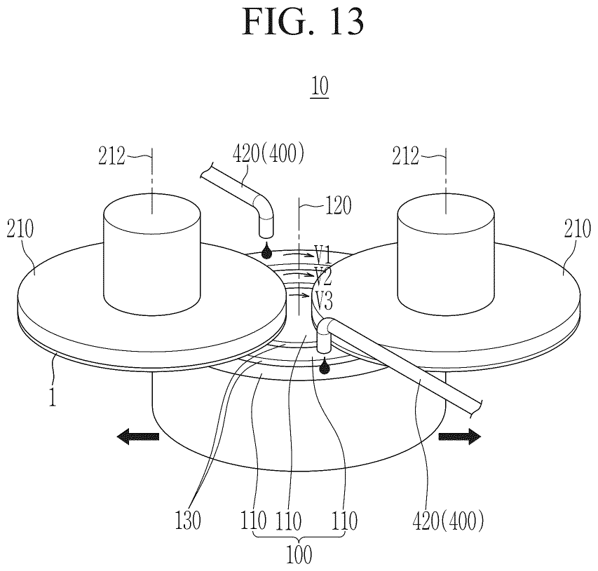

FIG. 13 is a view shown to describe a wafer cleaning device according to another embodiment.

As shown in FIG. 13, the wafer cleaning device 10 according to the other embodiment may include a brush module 100, at least one head portion 210 disposed above the brush module 100 to rotate with respect to a head axis 212 while supporting the other surface of a wafer 1, and a cleaning portion 400 supplying a cleaning solution to an upper surface of the brush module 100.

The brush module 100 may include a plurality of brushes 110 that are disposed so that an upper surface thereof faces one surface of the wafer 1, are independently rotated based on a central axis 120, and share a center.

The cleaning portion 400 shown in FIG. 13 may include a cleaning arm 420 disposed above the brush module 100, supplying the cleaning solution to the upper surface of the brush module 100, and having an arm shape.

However, the cleaning portion 400 is not limited to the cleaning arm 420 shown in FIG. 13. According to embodiments, the cleaning portion 400 may include at least one cleaning nozzle 410 disposed in at least one gap 130 between the plurality of brushes 110 (see FIGS. 6A to 8).

The embodiment of FIG. 13 has a structure in which the head portion 210 supports one surface of the wafer 1 so that it does not include a support portion 200 supporting the one surface of the wafer 1 and a roller 300 supporting a side surface of the wafer 1 (see FIG. 2 and FIG. 3).

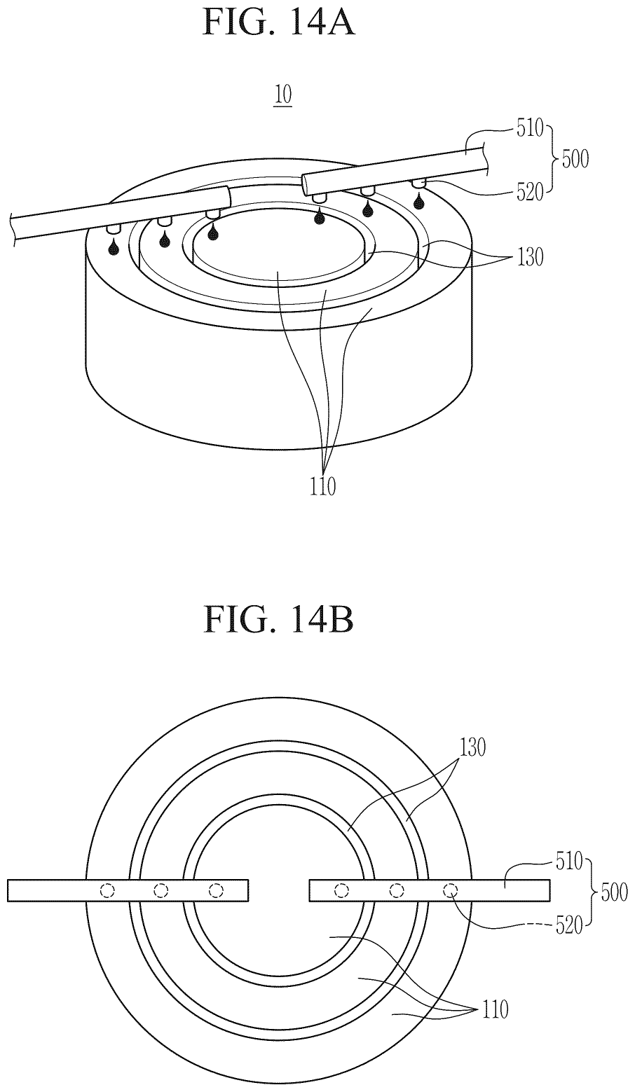

FIGS. 14A to 17B are views for describing a wafer cleaning device according to another embodiment.

First, FIG. 14A is a view of the wafer cleaning device 10 seen from the side, and FIG. 14B is a view of the wafer cleaning device 10 of FIG. 14A seen from above.

As shown in FIGS. 14A to 17B, the wafer cleaning device 10 according to the other embodiment may include a brush module 100 and a brush cleaning portion 500 (e.g., a brush cleaner) disposed above the brush module 100 to clean an upper surface of the brush module 100.

The brush module 100 may include a plurality of brushes 110 that are disposed so that an upper surface of the plurality of brushes 110 faces one surface of a wafer 1 and share a central axis 120 (see FIG. 2), and the plurality of brushes 110 may be independently rotated based on the central axis 120.

The brush cleaning portion 500 may include an arm portion 510 (e.g., an arm) having a length, and at least one cleaning solution supply portion 520 (e.g., a cleaning solution supply outlet) disposed at the arm portion 510 and supplying a cleaning solution toward the upper surface of the brush module 100.

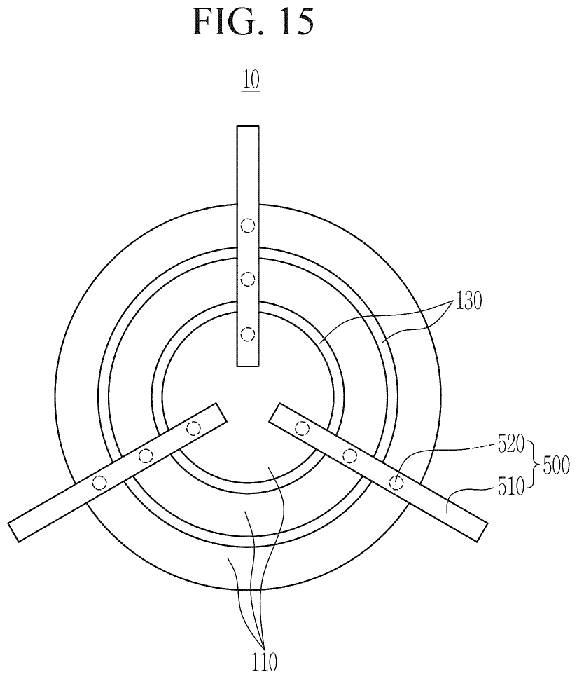

FIGS. 14A to 14B show the embodiment including two brush cleaning portions 500 that clean the brush module 100, and FIG. 15 shows an embodiment including three brush cleaning portions 500. The number of the brush cleaning portions 500 is not limited to those shown in FIGS. 14A to 15.

In the wafer cleaning device 10 of FIG. 14, the brush cleaning portion 500 may clean the upper surface of the brush module 100.

To clean the wafer 1 using a brush module 100 that is clean, the wafer 1 may be cleaned by disposing the wafer 1 between the brush cleaning portion 500 and the brush module 100.

According to an embodiment, the wafer 1 may be supported by a support portion 200 (see FIG. 2 and FIG. 3), or may be supported by the head portion 210 (see FIG. 13).

Here, components supporting the wafer 1 and the brush cleaning portion 500 may be disposed so as not to collide with each other.

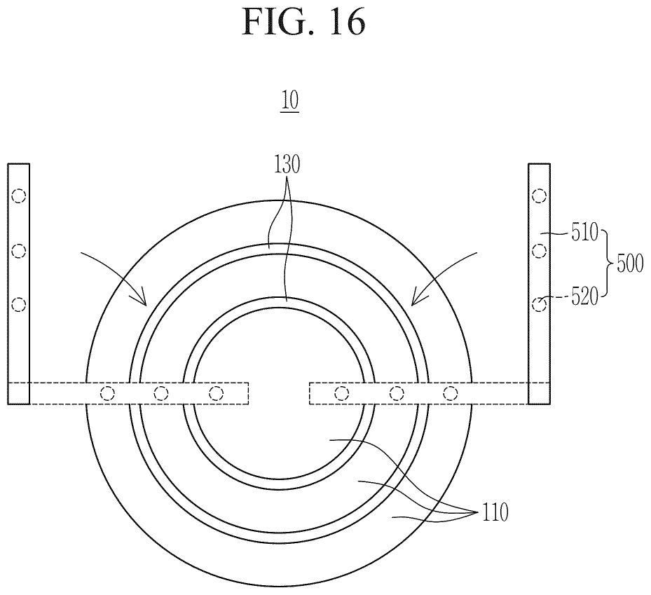

FIG. 16 shows the wafer cleaning device 10 including a brush cleaning portion 500 that is rotatable. As shown in FIG. 16, each of two arm portions 510 may rotate with respect to an axis at an outer end of the wafer 1.

A cleaning solution supplied from the brush cleaning portion 500 may be a cleaning solution generally used when the brush used to clean the wafer 1 in a cleaning process of the wafer 1 is cleaned. The cleaning solution may further include a DI Water (DIW).

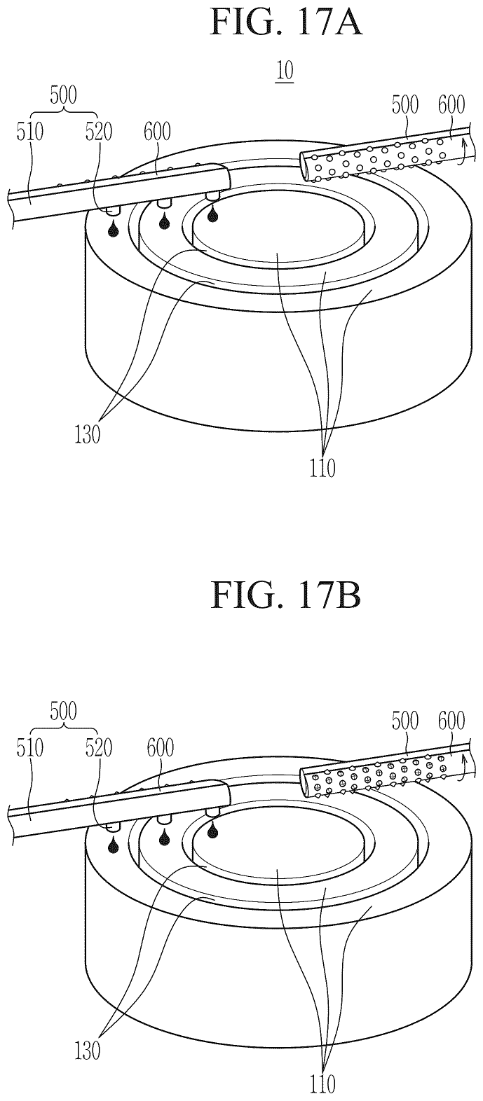

FIGS. 17A to 17B shows another embodiment in which the wafer cleaning device 10 may further include a roll-type brush 600 for cleaning the brush module 100 above the upper surface of the brush module 100.

The roll-type brush 600 may be disposed close to (e.g., on) at least one of the brush cleaning portions 500, and may be disposed parallel to a length direction of the brush cleaning portion 500. As shown in FIG. 17A and FIG. 17B, the roll-type brush 600 may have a structure that rotates around an axis in a length direction of the roll-type brush 600.

As shown in FIG. 17A, the roll-type brush 600 may be a brush made of only polymer that is used in a general CMP process.

Unlike FIG. 17A, a diamond tip may be further included on a surface of the roll-type brush 600 (see FIG. 17B). The diamond tip may have the same shape as a shape of a diamond provided at a disk that conditions a polishing pad.

As shown in FIGS. 14A to 17B, the wafer cleaning device 10 is capable of self-cleaning the brush module 100 itself. Accordingly, reverse contamination of the brush module 100 may be prevented and, since a replacement cycle of the brush module 100 may be lengthened, productivity may be improved.

According to embodiments of the present disclosure, the wafer cleaning device 10 may further include at least one actuator that is configured to cause any number of the components of the wafer cleaning device 10 to move (e.g., translate and/or rotate) as described in embodiments the present disclosure. For example, the at least one actuator may be configured to cause one or more (e.g., some or all) from among the brush module 100 (including the plurality of brushes 110), the support portions 200, the rollers 300, the head portions 210, the arm portions 510, the roll-type brush 600, etc., to move (e.g., translate and/or rotate).

While non-limiting example embodiments of the present disclosure have been described in connection with the accompanying drawings, it is to be understood that embodiments of the present disclosure are not limited to the example embodiments. On the contrary, various modifications and equivalent arrangements are included within the spirit and scope of the present disclosure.

What is claimed is:

1. A wafer cleaning device, comprising:
a brush module configured to face one surface of at least one wafer and rotate around a central axis of the brush module; and
at least one support that is adjacent to the brush module and configured to support the one surface of the at least one wafer,
wherein the brush module comprises a plurality of brushes sharing the central axis.

2. The wafer cleaning device of claim 1, further comprising at least one roller that is configured to contact a side surface of the at least one wafer while the brush module faces the one surface of the at least one wafer.

3. The wafer cleaning device of claim 1, wherein the plurality of brushes are configured to independently rotate around the central axis.

4. The wafer cleaning device of claim 1, wherein the plurality of brushes are separated from each other by at least one gap.

5. The wafer cleaning device of claim 4, further comprising a cleaning nozzle within the at least one gap, the cleaning nozzle configured to supply a cleaning solution to an upper surface of the brush module while the upper surface of the brush module is facing the at least one wafer.

6. The wafer cleaning device of claim 1, further comprising a cleaning arm above the brush module, the cleaning arm configured to supply a cleaning solution to an upper surface of the brush module while the upper surface of the brush module is facing the at least one wafer.

7. The wafer cleaning device of claim 1, wherein the at least one support is configured to support the at least one wafer in a non-contact state by supplying a fluid toward the one surface of the at least one wafer.

8. The wafer cleaning device of claim 1, wherein the at least one support is a plurality of supports, and the at least one wafer is a plurality of wafers.

9. The wafer cleaning device of claim 8, wherein the brush module is configured to face at least a portion of each of the plurality of wafers.

10. The wafer cleaning device of claim 1, wherein the brush module is configured to move, with respect to the at least one wafer, in a direction parallel to the one surface of the at least one wafer.

11. The wafer cleaning device of claim 1, wherein a plurality of nodules are on an upper surface of each brush among the plurality of brushes.

12. The wafer cleaning device of claim 11, wherein a shape of the plurality of nodules on a first brush, from among the plurality of brushes, is different from a shape of the plurality of nodules on a second brush, among the plurality of brushes.

13. The wafer cleaning device of claim 11, wherein the plurality of nodules on one of the plurality of brushes have a plurality of shapes.

14. The wafer cleaning device of claim 11, wherein the plurality of nodules on the plurality of brushes are uniformly disposed.

15. The wafer cleaning device of claim 11, wherein the plurality of nodules on the plurality of brushes are non-uniformly disposed.

16. The wafer cleaning device of claim 11, wherein an arrangement of the plurality of nodules on a first brush, from among the plurality of brushes, is different from an arrangement of the plurality of nodules on a second brush, among the plurality of brushes.

17. A wafer cleaning device, comprising:
a brush module comprising an upper surface that is configured to face a first surface of a wafer, the brush module configured to rotate around a central axis of the brush module;
a head portion comprising at least one body that is above the brush module, the at least one body configured to rotate around an axis of the head portion in a state in which the at least one body supports a second surface of the wafer, opposite of the first surface; and
a cleaner that is configured to supply a cleaning solution to the upper surface of the brush module,
wherein the brush module comprises a plurality of brushes that are configured to rotate around the central axis.

18. The wafer cleaning device of claim 17, wherein gaps are between the plurality of brushes.

19. A wafer cleaning device, comprising:
a brush module comprising a plurality of brushes sharing a central axis, the plurality of brushes configured to independently rotate around the central axis, and an upper surface of the brush module is configured to face a first surface of a wafer; and
a brush cleaner above the brush module and configured to clean the upper surface of the brush module,
wherein the brush cleaner comprises:
an arm; and
a cleaning solution outlet that is on the arm and configured to supply a cleaning solution toward the upper surface of the brush module.

20. The wafer cleaning device of claim 19, further comprising a roll-type brush that is disposed in parallel with a length direction of the brush cleaner and configured to rotate around an axis extending in the length direction.
